(19) United States
(12) Patent Application Publication
(10) Pub. No.: US 2004/0156170 A1
(43) Pub. Date: Aug. 12, 2004

(54) Household appliance with a display device

(76) Inventors: Gerhard Mager, Cadolzburg (DE); Willibald Reitmeier, Hemau (DE)

Correspondence Address: LERNER AND GREENBERG, P.A., POST OFFICE BOX 2480, HOLLYWOOD, FL, 33022-2480, US

(21) Appl. No.: 10/683,729

(22) Filed: Oct. 10, 2003

Related U.S. Application Data
(63) Continuation of application No. PCT/EP02/03870, filed on Apr. 8, 2002.

(30) Foreign Application Priority Data
Apr. 10, 2001 (DE) 101 17 905.7

(51) Int. Cl. H05K 5/00

(52) U.S. Cl. 361/683

(57) ABSTRACT

In a household device a display unit includes a display device, which has a layer of material that can be influenced electrically pixel by pixel, i.e., picture element by picture element, so that any displays that are connected to the household appliance, can be seen on the display device.

### CROSS-REFERENCE TO RELATED APPLICATION

This application is a continuation of copending International Application No. PCT/EP02/03870, filed Apr. 8, 2002, which designated the United States and was not published in English.

### BACKGROUND OF THE INVENTION

### Field of the Invention

The invention relates to a household appliance with a display device with which information concerning the household appliance can be presented.

There are many known household appliances with a display device. For example, European Patent Application 0 715 235 B1 discloses a household appliance that is equipped with a display device. The household appliance has an operating panel on which pushbuttons for setting programs and additional functions are disposed and, in separate display blocks, optical display devices are disposed in the form of light-emitting diodes (LEDs. Apart from LEDs, also used are vacuum-fluorescent diodes (VFDs) and liquid crystals in liquid crystal displays (LCDs).

### SUMMARY OF THE INVENTION

It is accordingly an object of the invention to provide a household appliance with a display device that overcomes the hereinafore-mentioned disadvantages of the heretofore-known devices of this general type and that equips the appliance with a novel display device.

An “electronic paper” (“E-paper”), which is also referred to as an Electrophoretic Imaging Display (EPID), has become known. The layer of material has translucent hollow beads that are filled with a dye and have a diameter of about 250 μm. The hollow beads are embedded in a transparent matrix electrode. Positively charged white pigments, which move in the electric field toward the upper side or the underside of the hollow beads according to the direction of the field, float in a liquid. If they move toward the upper side of the hollow beads, i.e., to the face visible from the outside, the white color of the pigments becomes visible. If they move toward the underside of the hollow beads, the color of the dye liquid in which the hollow beads are embedded becomes visible. Even after the electric field, i.e., the control voltage, is no longer present, the white pigments remain in their position so that a non-volatile display is achieved. At present, resolutions of 100 dots/inch are possible. Each pixel of the layer of material is controlled by active matrix electronics of organic material.

According to another principle, a display device has a multiplicity of beads that are white on one side and dark on the other side. On one side, they are positively charged and, on the other side, they are negatively charged. When an external voltage is applied, the beads rotate according to the direction of the electric field such that either the white side or the dark side of the beads is facing the surface of the display.

The present invention equips a household appliance with a novel display device.

With the foregoing and other objects in view, in a household appliance, there is provided, in accordance with the invention, a display device having a layer of material that can be electrically influenced pixel by pixel such that information concerning the household appliance can be presented by the layer of material.

According to the present invention, the layer of material allows a large display area to be built up, allowing all the number, user inputs, operating states, manufacturer information, and, additionally, advertising texts to be presented on the surface of a household appliance.

The fact that the display information is retained even in the de-energized state or in a power-saving standby mode allows the last-input program or the last-existing operating state and the like to be kept for any desired period of time as the display on the layer of material.

A further advantage of the display device according to the invention is that a very large display area can be formed, allowing, for example, the entire front of a refrigerator or a washing machine or a dishwasher or else the cover plate of such an appliance to be used for display information. In such a case, information is not restricted to information specific to the appliance, but, instead, any desired displays can be realized so that, for example, even current news can be presented in words and/or images.

The layer of material for the display device is distinguished by a very small thickness, which lies below one 1 mm, while conventional displays have a thickness of between 4 and 8 mm.

For presenting information against the background, a number of variants can be chosen. For example, presenting the current information in a black color before a white background comes into consideration; alternatively, white display information can be presented before a blue background.

The display device according to the present invention is also distinguished by very good contrast values; a large CR value of up to 10 can be achieved luminous density of the activated pixels in relation to the non-activated pixels; such a contrast value can be achieved even when there is ambient light and with a large viewing angle range.

A further advantage of the present invention is that the display device can also be disposed on a curved surface. Therefore, it can be applied both on a convex surface of a refrigerator and on the curved surface of a vacuum cleaner housing and also on a, for example, conically tapering, surface of a water boiler.

In accordance with another feature of the invention, there is provided at least one unit selected from the group consisting of an operating unit, a control unit of the household appliance, and an external unit, in particular a computer, the at least one unit generating a display on the electronic paper.

In accordance with a further feature of the household appliance according to the present invention, the display device is interrupted by an operating element, in particular, by a program selector switch or a button. The advantage of such a configuration is that the program selector switch or the button or the other operating element can be used for displaying related functions or displays or operating tips in each case before, during, or after actuation of the operating element in the area around the operating element on the layer of material.

In a further advantageous configuration of the present invention, the layer of material has been adhesively attached as a film onto a surface of plastic, glass, wood, or metal. Alternatively, the layer of material has been introduced into a frame, which, for its part, is fastened on an outer surface or against an outer surface of the household appliance.

One particular advantage of the present invention is that the display device may also include a membrane keyboard. In such a case, the operator can obtain feedback on the inputs made by the operator directly through the display panel or the display device. In such a case, a display that gives an indication of the actuation performed or functions brought about within the household appliance by the actuation appears after actuation of an operating panel disposed within the display device, either within the operating panel or outside the operating panel, preferably, in its vicinity.

Alternatively, a touch screen can also be combined with the display device according to the invention. In such a case, the touch film is applied either on or under the E-paper. Such a configuration has the advantage that the user receives feedback directly at the position of the button over the E-paper. Operating the touch film can be carried out individually during the production of the household appliance at the end of the line. Preferably, the E-paper layer can also be used in certain areas as a touch film.

In an alternative embodiment, the layer of material is not attached on the household appliance but on another object that is in connection with the household appliance through a data transmission connection. In such a case, the household appliance has an interface through which it communicates with the object so that communication between the functions input by the operator on the object and the household appliance is possible and that, on the other hand, a check-back signal is presented on the display device on the object. The object is, for example, a remote operating device, which is provided individually for the household appliance or with which a number of different appliances, in particular, a number of different household appliances, can be remotely operated. Preferably, the connection between the object and the appliance is a wireless connection for transmitting data therebetween.

With the objects of the invention in view, there is also provided a household appliance display structure, including a display device, with which information concerning the household appliance can be presented, the display device being an electronic paper electrically influenced pixel-by-pixel.

With the objects of the invention in view, there is also provided a household appliance, including a housing having an outer surface and a display device, with which information concerning the household appliance can be presented, the display device being an electronic paper electrically influenced pixel-by-pixel and being disposed at the outer surface.

The object, preferably, has a further communication interface with respect to an external computer to be able to display news and information, in particular, from the manufacturer of the household appliance, more particularly, with regard to the mode of operation of the household appliance to be controlled and to be operated. In particular, consultative communication between the operator and the external computer or between the operator and the household appliance is also possible by the remote control device.

A further advantage of the invention is that, in the case of a household appliance, it is also possible to dispense with printing on the molded front panel because the layer of material assumes this function because it is possible, on one hand, to provide fixed displays, such as, for example, the name of the manufacturer or the display of a brand, and, on the other hand, to present displays that either relate to user prompting or are prescribed by the user.

The display device can be operated as a decentralized display module with power supplied through batteries and/or through a plug power supply unit and can be applied, in particular, adhesively attached, anywhere on free surfaces, including an associated driver and control unit and a radio module.

Personal and individual labeling and setting of the front panel is made possible by the display device according to the invention. In such a case, the forming of the personal panel setting can be operated by a menu, by code input, name input, voice input, or by a biometric identification, for example, fingerprint identification, and also with automatic adaptation to the accustomed practices of the user.

In addition to the presentation of the display device that can be electrically influenced, it can also be provided that this partly has conventional printing, in particular, on its front surface, more particularly, an edge region, for example, with the name of the manufacturer. The present invention allows both the inputs of the operator and the functions of the household appliance to be presented over a large area in a simple way.

Special series of a household appliance can be realized advantageously by a differentiated display image on the display device according to the present invention, without generating the expenditure of further costs in manufacture. The display of the device can also be used for reducing variants and also in customer service, in that the individual display image is only programmed in situ at the customer's premises or only input in the retail outlet when it has been established that special series and that types are most in demand.

Depending on the operating mode of the household appliance, the display image can be adapted, in an optimized manner, by the layer of material over a large area—in the ideal case over the entire front panel—to the interactive operator prompting, in particular, ergonomics.

The non-volatile display information on the display device allows it to be conveyed while the household appliance is on display in the sales area or an advertising message or other information to be conveyed otherwise for advertising purposes, with large-area animations also being possible.

It is, consequently, found that benefits for the user are greatly increased by the properties of the display device according to the invention.

Apart from information specifically related to the household appliance, online tips, such as, for example, user instructions, information on washing and fabrics, cooking recipes, and further information can be presented by the manufacturer of the household appliance.

According to the present invention, a household appliance can be conceived and used as a large decentralized display system in a household. A household appliance that is present in any case in a room, for example, in the kitchen or in a laundry room, can be used at the same time for the transmission of images and text information.

The display device can also be applied at a subsequent time. The fact that the E-paper is a thin layer allows it also to be applied by new production methods.

The display device may also serve for a plurality of interconnected household appliances, which can be operated alternately by an operating units connected to the display device.

Other features that are considered as characteristic for the invention are set forth in the appended claims.

Although the invention is illustrated and described herein as embodied in a household appliance with a display device, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a front perspective view of a household appliance with a display device according to the invention;

FIG. 2 is a front perspective view of an operating device with a display device according to the invention for the appliance of FIG. 1; and

FIG. 3 is a cross-sectional view of an embodiment of the display device of the appliance of FIG. 1.

### DESCRIPTION OF THE PREFERRED EMBODIMENTS

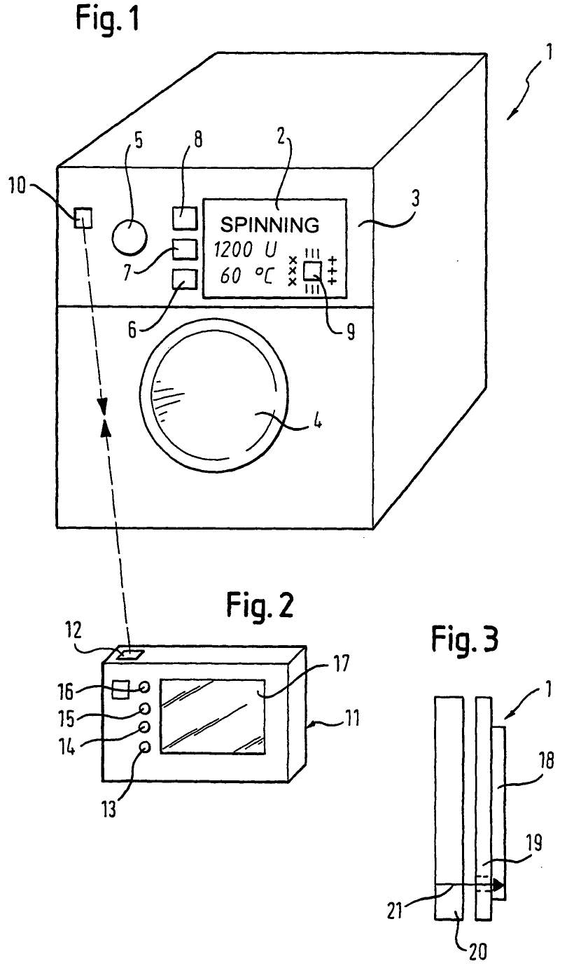

Referring now to the figures of the drawings in detail and first, particularly to FIG. 1 thereof, there is shown a household appliance 1, for example, a washing machine, a dishwasher, an oven, or a refrigerator, equipped with a display device 2. The display device 2 is preferably integrated into an operating panel 3. The operating panel 3 is disposed in a region above a loading door 4 for a laundry drum if the household appliance 1 is a washing machine. Apart from the display device 2, a program selector switch 5 is provided in the region of the operating panel 3. When a specific setting of the program is selected in the selector switch 5, the associated data are presented on the display device 2, for example, “SPINNING, 1200 rpm, 60° C.”. Additionally provided are further switches or buttons 6, 7, and 8, which are disposed next to the display device. A switch 9, which may, for example, also be a rotary switch, is disposed in the region inside the display device 2. Depending on the operating mode of the switch 9, displays are made visible in the region around the switch 9 of the display device 2.

In addition, the household appliance 1 is equipped with an interface 10 for the inputting or changing of process parameters and/or reading out of data from the microprocessor controller of the household appliance and also, in particular, the controller of the display device 2 by an external data processing device such as the operating device 11 shown in FIG. 2.

The operating device 11 has an interface 12 corresponding to interface 10 so that a bi-directional wireless connection between the interface 10 and the interface 12 is possible, in particular, when an operator of the operating device 11 operates the household appliance 1. In such a case, the operating device 12 is constructed advantageously such that a plurality of household appliances, in particular, the household appliance 1 and, in addition, a dishwasher, an oven, a microwave, a refrigerator, a coffee maker, an egg boiler, etc. can be operated. The operator uses a selector switch 13 initially to select the household appliance desired by the operator and, then, uses further switches 14 to 16 to determine specific functions of the household appliance respectively selected. By a display device 17, which is constructed like the display device 3 from the layer of material that can be electrically influenced pixel by pixel, the user, then, reads information input by the user and/or information prescribed by the selected household appliance on its function, status, functional capabilities, power consumption, program sequence, program duration etc. In addition, information and, additionally, information relevant to the user can also be read off or input by the latter by the display device 17.

In FIG. 3, a display device 18 including E-paper that has been applied on a front panel 19 is represented in cross section; the front panel is disposed on an appliance door 20 by non-illustrated holding measures. The high flexibility of the display device 18 allows it to be applied both during the manufacture of the household appliance and at a later time to the appliance. The display device 18 has, on its underside, a connection for supplying power and data. Both the front panel 19 and the appliance door 20 are provided with a bore 21 for the leading through of power supply and data lines. Such bores 21 may also be made in the delivered state, that is, at the user's premises so that the functionality of the household appliance also can be extended by the display device according to the invention being applied at a subsequent time.

The present invention provides a household appliance 1 with a display device 2 that has a layer of material that can be electrically influenced pixel by pixel, i.e., picture element by picture element so that any desired displays relating to the household appliance 1 can be made visible on the display device 2.

We claim:

1. In a household appliance, a display structure, comprising:
a display device, with which information concerning the household appliance can be presented, said display device being an electronic paper electrically influenced pixel-by-pixel.

2. The display structure according to claim 1, further comprising at least one unit selected from the group consisting of an operating unit, a control unit of the household appliance, and an external unit, said at least one unit generating a display on said electronic paper.

3. The display structure according to claim 2, wherein said external unit is a computer.

4. The display structure according to claim 1, wherein:
the household appliance has a curved surface; and
said electronic paper is applied on said curved surface.

5. The display structure according to claim 1, wherein:
the appliance has an operating element; and
the operating element interrupts said electronic paper.

6. The display structure according to claim 5, wherein said operating element is one of the group consisting of a program selector switch and a button.

7. The display structure according to claim 1, wherein:
the appliance has a surface of one of the group consisting of plastic, glass, wood, and metal; and
said electronic paper is adhesively attached as a film onto the surface.

8. The display structure according to claim 1, wherein:
an object external to the appliance has an outer surface;
said electronic paper is attached to said outer surface of said object; and
the object and the appliance have a connection for transmitting data therebetween.

9. The display structure according to claim 1, wherein the object is an operating device.

10. The display structure according to claim 9, wherein the connection is a wireless connection.

11. The display structure according to claim 1, wherein said display device is a membrane keyboard for operator input.

12. The display structure according to claim 1, wherein said display device is a touch screen for operator input.

13. A household appliance display structure, comprising:
a display device, with which information concerning the household appliance can be presented, said display device being an electronic paper electrically influenced pixel-by-pixel.

14. The display structure according to claim 13, further comprising at least one unit selected from the group consisting of an operating unit, a control unit of a household appliance, an external unit, and an external computer, said at least one unit generating a display on said electronic paper.

15. The display structure according to claim 13, wherein said electronic paper is to be applied on a curved surface of a household appliance.

16. The display structure according to claim 13, wherein said electronic paper is to be interrupted by an operating element of a household appliance.

17. The display structure according to claim 16, wherein the operating element is one of the group consisting of a program selector switch and a button.

18. The display structure according to claim 13, wherein:
said electronic paper adhesively attaches as a film onto a surface of a household appliance; and
the surface is one of the group consisting of plastic, glass, wood, and metal.

19. The display structure according to claim 13, wherein:
said electronic paper adhesively attaches as a film onto an outer surface of an object external to a household appliance; and
the object and the appliance have a connection for transmitting data therebetween.

20. The display structure according to claim 19, wherein the connection is a wireless connection.

21. The display structure according to claim 13, wherein said display device is a membrane keyboard for operator input.

22. The display structure according to claim 13, wherein said display device is a touch screen for operator input.

23. A household appliance, comprising:
a housing having an outer surface; and
a display device, with which information concerning the household appliance can be presented, said display device being an electronic paper electrically influenced pixel-by-pixel and being disposed at said outer surface.
